(19) United States
(12) Patent Application Publication
(10) Pub. No.: US 2025/0169286 A1
(43) Pub. Date: May 22, 2025

(54) DISPLAY DEVICE AND METHOD OF FABRICATING THE SAME

(71) Applicant: Samsung Display Co., LTD., Yongin-si (KR)

(72) Inventors: Che Ho LEE, Yongin-si (KR); Sae Bom AHN, Yongin-si (KR); So Yeon JEONG, Yongin-si (KR); Won Je JO, Yongin-si (KR)

(21) Appl. No.: 18/676,352

(22) Filed: May 28, 2024

(30) Foreign Application Priority Data
Nov. 21, 2023 (KR) 10-2023-0161837

(51) Int. Cl. H10K 59/122; H10K 59/12; H10K 59/80

(52) U.S. Cl. CPC H10K 59/122; H10K 59/1201; H10K 59/873

(57) ABSTRACT

A display device includes: a substrate comprising an emission area and a non-emission area; a first light emitting element on the emission area of the substrate; a pixel defining layer on the non-emission area of the substrate and defining a first opening; a bank layer on the pixel defining layer, defining a second opening, and containing a conductive material; a first encapsulation layer on the first light emitting element and containing an inorganic material; and a second encapsulation layer on the first encapsulation layer and containing an organic material, wherein a cavity is formed between the first encapsulation layer and the bank layer in a direction perpendicular to the substrate, the cavity overlaps the emission area and the non-emission area, and the cavity is filled by the second encapsulation layer.

### CROSS-REFERENCE TO RELATED APPLICATION

The present application claims priority to and the benefit of Korean Patent Application No. 10-2023-0161837, filed on Nov. 21, 2023, in the Korean Intellectual Property Office, the entire disclosure of which is incorporated herein by reference.

### BACKGROUND

### 1. Field

Aspects of some embodiments of the present disclosure relate to a display device and a method of fabricating the same.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and smart televisions. The display device may be a flat panel display device such as a liquid crystal display device, a field emission display device and an organic light emitting display device.

Among flat panel display devices, in a light emitting display device, because each pixel of a display panel generally includes a light emitting element capable of emitting light by itself, images can be displayed without a backlight unit providing light to the display panel.

Recently, as various electronic devices have developed, consumer demand for high-resolution display devices is increasing. Because high-resolution display devices may require high pixel integration density, the spacing between light emitting elements that overlap each emission area may be narrowed. Accordingly, a high-resolution display device may be formed by a pattern process that forms individual pixels rather than a mask process.

The above information disclosed in this Background section is only for enhancement of understanding of the background and therefore the information discussed in this Background section does not necessarily constitute prior art.

### SUMMARY

Aspects of the present disclosure provide a high-resolution display device by forming a light emitting element through a photo pattern process without a mask.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to some embodiments of the present disclosure, a display device includes a substrate comprising an emission area and a non-emission area; a first light emitting element on the emission area of the substrate; a pixel defining layer located on the non-emission area of the substrate and defining a first opening; a bank layer located on the pixel defining layer, defining a second opening, and containing a conductive material; a first encapsulation layer located on the first light emitting element and containing an inorganic material; and a second encapsulation layer located on the first encapsulation layer and containing an organic material, wherein a cavity is formed between the first encapsulation layer and the bank layer in a direction perpendicular to the substrate, the cavity overlaps the emission area and the non-emission area, and the cavity is filled by the second encapsulation layer.

According to some embodiments, the display device may further include a second light emitting element spaced apart from the first light emitting element with the bank layer interposed therebetween, wherein the first light emitting element comprises: a first anode electrode on the substrate; a first light emitting layer on the first anode 1 electrode; and a first cathode electrode on the first light emitting layer, and the second light emitting element comprises: a second anode electrode spaced apart from the first anode electrode with the pixel defining layer interposed therebetween; a second light emitting layer on the second anode electrode; and a second cathode electrode on the second light emitting layer.

According to some embodiments, the bank layer may include a first side surface in contact with the first cathode electrode; a second side surface in contact with the second cathode electrode; and a first surface which is in contact with the second encapsulation layer and connects the first side surface to the second side surface.

According to some embodiments, the first cathode electrode and the second cathode electrode may be electrically connected through the bank layer.

According to some embodiments, the first light emitting layer may be in contact with the first side surface, and the second light emitting layer is in contact with the second side surface.

According to some embodiments, the first encapsulation layer may include a first inorganic layer in contact with the first light emitting element and a second inorganic layer in contact with the second light emitting element, and the first inorganic layer and the second inorganic layer are spaced apart from each other in a portion overlapping the non-emission area.

According to some embodiments, a cavity formed between the bank layer and the first inorganic layer in the direction perpendicular to the substrate may have a first height, and a cavity formed between the bank layer and the second inorganic layer has a second height.

According to some embodiments, the first height and the second height may be different from each other.

According to some embodiments, the second height may be greater than the first height.

According to some embodiments, the first surface may be not in contact with the first encapsulation layer, and the first surface is in contact with the second encapsulation layer.

According to some embodiments, the first surface may be spaced apart from the first encapsulation layer with the cavity interposed therebetween.

According to some embodiments, the display device may further include a residual pattern between the first anode electrode and the pixel defining layer in the direction perpendicular to the substrate, wherein the residual pattern may be in contact with the first light emitting layer.

According to some embodiments, in a plan view, the first opening may be completely surrounded by the second opening.

According to some embodiments, the display device may further include an auxiliary encapsulation layer between the first encapsulation layer and the second encapsulation layer, wherein the auxiliary encapsulation layer completely covers the first encapsulation layer in a portion overlapping the emission area and the non-emission area, and the auxiliary encapsulation layer is in contact with the first surface, and the auxiliary encapsulation layer completely covers the first surface.

According to some embodiments of the present disclosure, a substrate include a first emission area, a second emission area, and a non-emission area between the first emission area and the second emission area; a first light emitting element on the first emission area of the substrate; a second light emitting element on the second emission area of the substrate; a pixel defining layer located on the non-emission area of the substrate and defining a first opening; a bank layer defining a second opening on the pixel defining layer; a first inorganic layer located on the first light emitting element; a second inorganic layer located on the second light emitting element and spaced apart from the first inorganic layer; and an organic encapsulation layer located on the first inorganic layer and the second inorganic layer, wherein the first light emitting element and the first inorganic layer are in contact with one side 1 surface of the bank layer facing the first emission area, the second light emitting element and the second inorganic layer are in contact with the other side surface of the bank layer facing the second emission area, and the first inorganic layer and the second inorganic layer are spaced apart from each other without overlapping the non-emission area.

According to some embodiments, the first opening may be inside the second opening.

According to some embodiments, the bank layer may include a first surface facing the organic encapsulation layer, and the first inorganic layer and the second inorganic layer comprise a protrusion which protrudes more toward the organic encapsulation layer than the first surface.

According to some embodiments, the display device may further include a residual pattern between the substrate and the pixel defining layer in a direction perpendicular to the substrate, wherein the residual pattern and the protrusion may do not overlap each other.

According to some embodiments of the present disclosure, a method of fabricating a display device include forming a substrate comprising an emission area and a non-emission area, an anode electrode on the emission area of the substrate and a sacrificial layer on the anode electrode, and forming a pixel defining layer completely covering the sacrificial layer and the substrate, and a bank material layer completely covering the pixel defining layer; forming a photoresist on the bank material layer, etching the bank material layer and the pixel defining layer overlapping the anode electrode to expose the sacrificial layer, and then etching a sidewall of the bank material layer and the sacrificial layer to expose the anode electrode and form a bank layer; forming a light emitting layer and a cathode electrode on the anode electrode and the photoresist, and forming a first encapsulation layer on the cathode electrode; and removing the light emitting layer, the cathode electrode, and the first encapsulation layer located in other areas excluding the light emitting layer, the cathode electrode, and the first encapsulation layer located in the emission area and around the emission area, wherein in the removing of the light emitting layer and the cathode electrode, a cavity is formed between the first encapsulation layer and the bank layer in a direction perpendicular to the substrate.

According to some embodiments, in the etching of the sidewall of the bank material layer to form the bank layer, the photoresist may form a tip which protrudes more toward the emission area than a sidewall of the bank layer.

The display device according to some embodiments may form the light emitting element that overlaps each emission area without a mask by using a photoresist with a tip protruding toward the emission area during a fabricating process of the display device. Further, the display device according to some embodiments may include a bank structure including a conductive material in a portion overlapping a non-emission area.

Accordingly, the display device according to some embodiments may form individual pixels spaced apart in a portion overlapping each emission area, and the individual pixels spaced apart may be electrically connected by a bank structure. As a result, the display device according to some embodiments may provide a high-resolution display device that is relatively easy to fabricate.

However, the characteristics of embodiments of the present disclosure are

not limited to those illustrated and described above and various other effects are incorporated herein.

### BRIEF DESCRIPTION OF THE DRAWINGS

The above and other aspects and features of embodiments according to the present disclosure will become more apparent by describing in more detail aspects of some embodiments thereof with reference to the attached drawings, in which:

FIG. 1 is a perspective view of an electronic device according to some embodiments;

FIG. 2 is a perspective view illustrating a display device included in the electronic device according to some embodiments;

FIG. 3 is a schematic cross-sectional view of the display device of FIG. 2 according to some embodiments;

FIG. 4 is a plan view illustrating the arrangement of the emission area in the display area of FIG. 3 according to some embodiments;

FIG. 5 is a schematic cross-sectional view of the display area taken along line X1-X1′ of FIG. 4 according to some embodiments;

FIG. 6 is an enlarged schematic cross-sectional view of the first emission area and the second emission area in FIG. 5 according to some embodiments;

FIG. 7 is an enlarged schematic cross-sectional view of the second emission area and the third emission area in FIG. 5 according to some embodiments;

FIG. 8 is a schematic cross-sectional view of a display layer according to some embodiments taken along line X1-X1′ of FIG. 4, according to some embodiments;

FIG. 9 is a schematic cross-sectional view of a display layer according to some embodiments taken along line X1-X1′ of FIG. 4, according to some embodiments;

FIG. 10 is a schematic cross-sectional view of the display layer according to some embodiments taken along line X1-X1′ of FIG. 4, according to some embodiments; and

FIGS. 11 to 19 are cross-sectional views illustrating a schematic fabricating method of a display layer included in the display device of FIG. 5 according to some embodiments.

### DETAILED DESCRIPTION

Hereinafter, aspects of some embodiments will be described in more detail with reference to the accompanying drawings, in which like reference numbers refer to 1 like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or any combination of one or more of a, b, and/or c.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

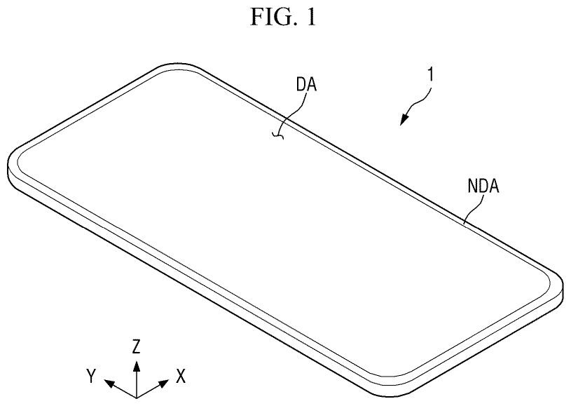

FIG. 1 is a schematic perspective view of an electronic device 1 according to some embodiments.

Referring to FIG. 1, the electronic device 1 displays moving images (e.g., video images) or still images (e.g., static images). The electronic device 1 may refer to any electronic device providing a display screen. Examples of the electronic device 1 may include, for example, a television, a laptop computer, a monitor, a billboard, an

Internet-of-Things device, a mobile phone, a smartphone, a tablet personal computer (PC), an electronic watch, a smart watch, a watch phone, a head-mounted display, a mobile communication terminal, an electronic notebook, an electronic book, a portable multimedia player (PMP), a navigation device, a game machine, a digital camera, a camcorder and the like, which provide a display screen.

FIG. 1 defines a first direction (X-axis direction), a second direction (Y-axis direction), and a third direction (Z-axis direction). The first direction (X-axis direction) and the second direction (Y-axis direction) may be perpendicular to each other, the first direction (X-axis direction) and the third direction (Z-axis direction) may be perpendicular to each other, and the second direction (Y-axis direction) and the third direction (Z-axis direction) may be perpendicular to each other. It may be understood that the first direction (X-axis direction) refers to a horizontal direction in the drawing, the second direction (Y-axis direction) refers to a vertical direction in the drawing, and the third direction (Z-axis direction) refers to an upward and downward direction (i.e., a thickness direction) in the drawing. In the following specification, unless otherwise stated, “direction” may refer to both of directions extending along the direction. Further, when it is necessary to distinguish both “directions” extending in both sides, one side will be referred to as “one side in the direction” and the other side will be referred to as “the other side in the direction.” Referring to FIG. 1, a direction in which an arrow indicating a direction is directed is referred to as one side, and an opposite direction thereto is referred to as the other side.

Hereinafter, for simplicity of description, when referring to the electronic device 1 or the surfaces of each member constituting the electronic device 1, one surface facing one side in the direction in which the image is displayed, that is, the third direction (Z-axis direction) is referred to as a top surface, and the opposite surface of the one surface is referred to as the other surface. However, the present disclosure is not limited thereto, and the one surface and the other surface of the member may be referred to as a front surface and a rear surface, respectively, or may also be referred to as a first surface or a second surface. In addition, in describing the relative position of each of the members of the electronic device 1, one side of the third direction (Z-axis direction) may be referred to as an upper side and the other side of the third direction (Z-axis direction) may be referred to as a lower side.

The shape of the electronic device 1 may be variously modified. For example, the electronic device 1 may have a shape such as a rectangular shape elongated in a horizontal direction, a rectangular shape elongated in a vertical direction, a square shape, a quadrilateral shape with rounded corners (vertices), other polygonal shapes and a circular shape.

The electronic device 1 may include a display area DA and a non-display area NDA. The display area DA is an area where a screen or images can be displayed, and the non-display area NDA is an area where a screen or images are not displayed. The display area DA may also be referred to as an active region, and the non-display area NDA may also be referred to as a non-active region. The display area DA may substantially occupy the center of the electronic device 1.

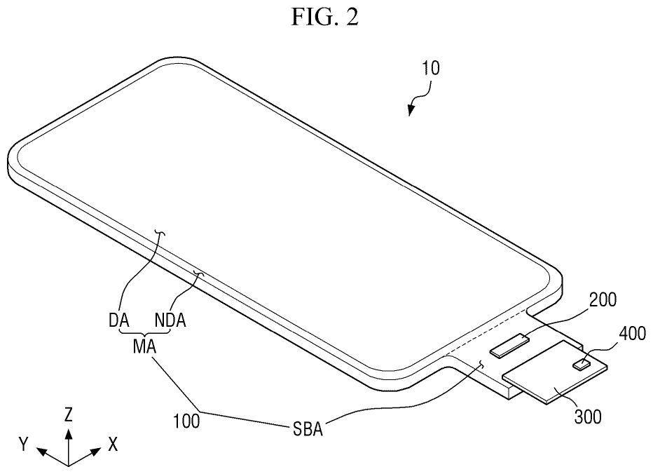

FIG. 2 is a perspective view illustrating a display device 10 included in the electronic device 1 according to some embodiments.

Referring to FIG. 2, the electronic device 1 according to one embodiment may include the display device 10. The display device 10 may provide a screen displayed by the electronic device 1. Examples of the display device 10 may include an inorganic light emitting diode display device, an organic light emitting display device, a quantum dot light emitting display device, a plasma display device and a field emission display device. In the following description, a case where an organic light emitting diode display device is applied as a display device will be exemplified, but embodiments according to the present disclosure are not limited thereto, and other display devices may be applied within the spirit and scope of embodiments according to the present disclosure.

The display device 10 may have a planar shape similar to the shape of the electronic device 1. For example, the display device 10 may have a shape similar to a rectangular shape, in a plan view, having short sides in a first direction (X-axis direction) and long sides in a second direction (Y-axis direction). The edge where the short side in the first direction (X-axis direction) and the long side in the second direction (Y-axis direction) meet may be rounded to have a curvature, but is not limited thereto and may be formed at a right angle. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA. The main region MA may include the display area DA including pixels displaying an image and the non-display area NDA arranged around (e.g., in a periphery or outside a footprint of) the display area DA.

The display area DA may emit light from a plurality of openings or a plurality of emission areas to be described later. For example, the display panel 100 may include a pixel circuit including switching elements, a pixel defining layer defining an emission area or an opening, and a self-light emitting element. For example, the self-light emitting element may include at least one of an organic light emitting diode (LED) including an organic light emitting layer, a quantum dot LED including a quantum dot light emitting layer, an inorganic LED including an inorganic semiconductor, or a micro LED, but is not limited thereto. In the following drawings, a case where the self-light emitting element is an organic light emitting diode is illustrated by way of example.

The non-display area NDA may be an area outside the display area DA. The non-display area NDA may be defined as an edge area of the main region MA of the display panel 100.

The sub-region SBA may be a region extending from one side of the main region MA. The sub-region SBA may include a flexible material which can be bent, folded or rolled. For example, when the sub-region SBA is bent, the sub-region SBA may overlap the main region MA in a thickness direction (e.g., the third direction (Z-axis direction)). The sub-region SBA may include the display driver 200 and a pad portion connected to the circuit board 300. According to some embodiments, the sub-region

SBA may be omitted, and the display driver 200 and the pad portion may be located in the non-display area NDA.

The display driver 200 may output signals and voltages for driving the display panel 100. The display driver 200 may be formed as an integrated circuit (IC) and mounted on the display panel 100 by a chip on glass (COG) method, a chip on plastic

(COP) method, or an ultrasonic bonding method. For example, the display driver 200 may be located in the sub-region SBA, and may overlap the main region MA in the thickness direction by bending of the sub-region SBA. For another example, the display driver 200 may be mounted on the circuit board 300.

The circuit board 300 may be attached to the pad portion of the display panel 100 by using an anisotropic conductive film (ACF). The circuit board 300 may be a flexible printed circuit board, a printed circuit board, or a flexible film such as a chip on film

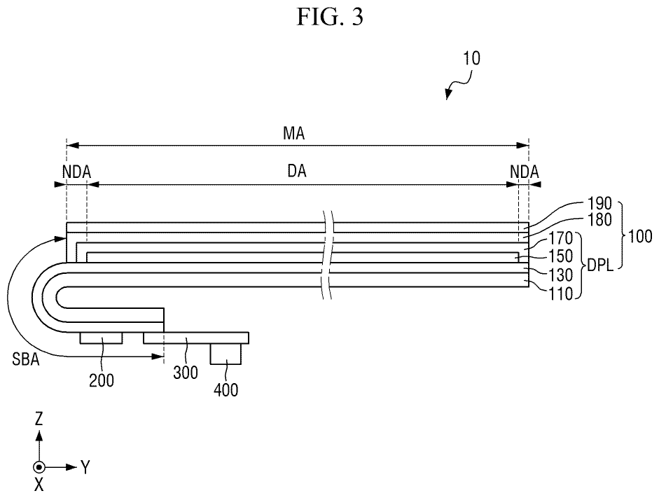

The touch driver 400 may be mounted on the circuit board 300. The touch driver 400 may be connected to a touch sensor layer 180 (see FIG. 3) of the display panel 100. The touch driver 400 may be formed as an integrated circuit.

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin film transistor layer 130, a display element layer 150, and a thin film encapsulation layer 170.

The substrate 110 may be a base substrate or a base member. The substrate 110 may be a flexible substrate which can be bent, folded or rolled without damaging the display device 10. For example, the substrate 110 may include a polymer resin such as polyimide (PI), but embodiments according to the present disclosure are not limited thereto. According to some embodiments, the substrate 110 may include a glass material or a metal material.

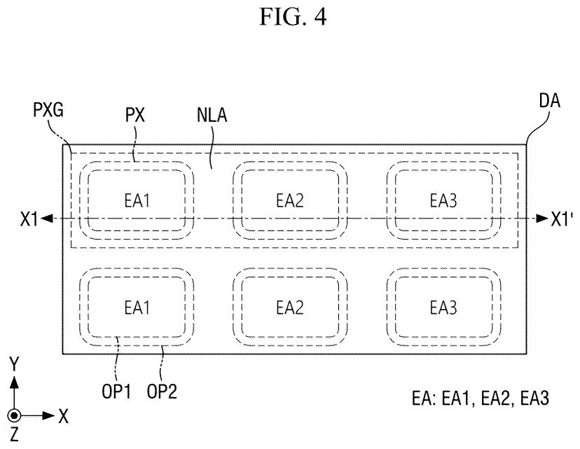

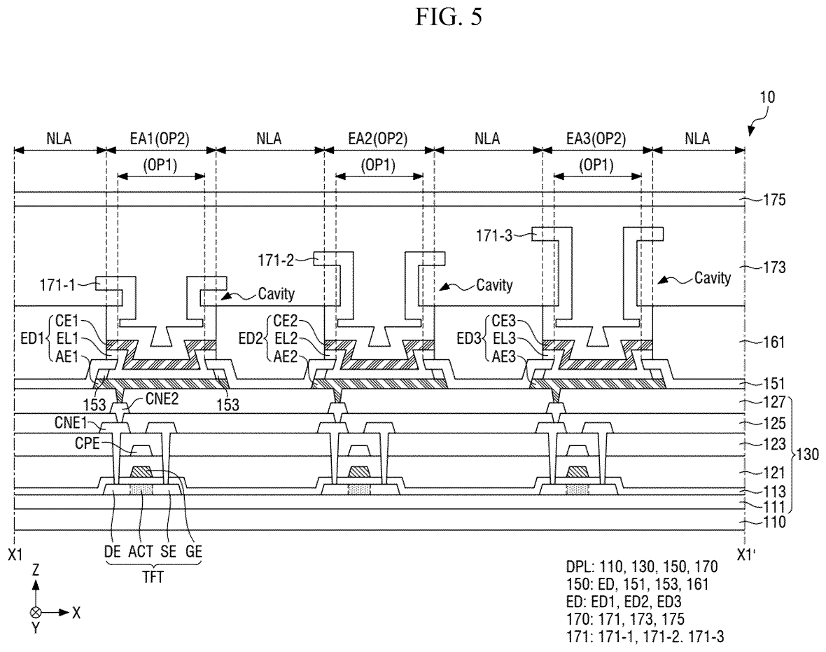

The thin film transistor layer 130 may be located on the substrate 110. The thin film transistor layer 130 may be located in the display area DA, the non-display area NDA, and the sub-region SBA. The thin film transistor layer 130 may include a plurality of thin film transistors TFT (see FIG. 5) constituting a pixel PX (see FIG. 4).

The display element layer 150 may be located on the thin film transistor layer 130. The display element layer 150 may be positioned to overlap the display area DA.

The display element layer 150 may include a plurality of display elements ED (see FIG. 5). For example, the display element according to some embodiments may include at least one of an organic light emitting diode (LED) including an organic light emitting layer, a quantum dot LED including a quantum dot light emitting layer, an inorganic LED including an inorganic semiconductor, or a micro LED, but embodiments according to the present disclosure are not limited thereto.

The thin film encapsulation layer 170 may be located on the display element layer 150. The thin film encapsulation layer 170 may be positioned to overlap the display area DA and the non-display area NDA. For example, the thin film encapsulation layer 170 may extend to cover the entirety of the display area DA and into the non-display area NDA. The thin film encapsulation layer 170 may cover the top surface and the side surface of the display element layer 150 and protect the display element layer 150 from external oxygen and moisture. The thin film encapsulation layer 170 may include at least one inorganic layer and at least one organic layer for encapsulating the display element layer 150.

The touch sensor layer 180 may be located on the thin film encapsulation layer 170. The touch sensor layer 180 may be positioned to overlap the display area DA and the non-display area NDA. The touch sensor layer 180 may sense the user's touch by using a mutual capacitance method or a self-capacitance method.

The color filter layer 190 may be located on the touch sensor layer 180. The color filter layer 190 may be positioned to overlap the display area DA and the non-display area NDA. The color filter layer 190 may absorb a part of light coming from the outside of the display device 10 to reduce reflected light due to external light. Accordingly, the color filter layer 190 may prevent or reduce color distortion caused by reflection of the external light.

Because the color filter layer 190 is directly located on the touch sensor layer 180, the display device 10 may not require a separate substrate for the color filter layer 190. Accordingly, the thickness of the display device 10 may be relatively small. In addition, the color filter layer 190 may be omitted according to some embodiments.

As illustrated in FIG. 3, a portion of the display layer DPL overlapping the sub-region SBA may be bent. When a portion of the display layer DPL is bent, the display driver 200, the circuit board 300, and the touch driver 400 may overlap the main region MA in the third direction (Z-axis direction).

FIG. 4 is a plan view illustrating an example arrangement of the emission area EA in the display area DA of FIG. 3.

Referring to FIG. 4, the display area DA according to some embodiments may include a plurality of first to third emission areas EA1, EA2, and EA3 and a non-emission area NLA. The non-emission area NLA may be positioned to surround the plurality of first to third emission areas EA1, EA2, and EA3.

The non-emission area NLA may block each light emitted from the plurality of first to third emission areas EA1, EA2, and EA3. Accordingly, the non-emission area NLA may assist in preventing or reducing the respective lights emitted from the plurality of first to third emission areas EA1, EA2, and EA3 from being mixed. An inorganic pixel defining layer 151 (see FIG. 5) and a bank layer 161 (see FIG. 5), which will be described later, may be located in the non-emission area NLA.

The emission area EA may include a first emission area EA1, a second emission area EA2, and a third emission area EA3 emitting light of different colors. The first to third emission areas EA1, EA2, and EA3 may emit red, green, or blue light, respectively, and the color of the light emitted from each of the first to third emission areas EA1, EA2 and EA3 may be different depending on the type of a light emitting element ED, which will be described later. According to some embodiments, the first emission area EA1 may emit red light of a first color, the second emission area EA2 may emit green light of a second color, and the third emission area EA3 may emit green light of a third color, but embodiments according to the present disclosure are not limited thereto. In the drawing, the size and shape of each of the first to third emission areas EA1, EA2, and EA3 are illustrated to be the same, but are not limited thereto. The size and shape of each of the first to third emission areas EA1, EA2, and EA3 may be freely adjusted according to required characteristics.

The plurality of first to third emission areas EA1, EA2, and EA3 may be defined by a first opening OP1 and a second opening OP2. For example, the first opening OP1 may be defined by the inorganic pixel defining layer 151, which will be described later, and the second opening OP2 may be defined by the bank layer 161, which will be described later. In a plan view, the second opening OP2 may completely surround the first opening OP1, and the second opening OP2 may be completely surrounded by the non-emission area NLA.

According to some embodiments, at least one first emission area EA1, at least one second emission area EA2, and at least one third emission area EA3 located adjacent to each other may constitute one pixel group PXG. The pixel group PXG may be a minimum unit that emits white light. However, the type and/or number of the first to third respective emission areas EA1, EA2, and EA3 constituting the pixel group PXG may be changed variously depending on the embodiments.

FIG. 5 is a schematic cross-sectional view of the display area DA taken along line X1-X1′ of FIG. 4. FIG. 5 is a partial cross-sectional view of the display device 10 overlapping the display area DA and illustrates a schematic cross section of the display layer DPL. That is, FIG. 5 illustrates a cross section of the substrate 110, the thin film transistor layer 130, the display element layer 150, and the thin film encapsulation layer 170 of the display device 10 according to some embodiments. Because the substrate 110 is explained in FIG. 3 above, it will be omitted.

Referring to FIG. 5, the thin film transistor layer 130 may be located on the substrate 110. The thin film transistor layer 130 may include a first buffer layer 111, the thin film transistor TFT, a gate insulating layer 113, a first interlayer insulating layer 121, a capacitor electrode CPE, a second interlayer insulating layer 123, a first connection electrode CNE1, a first via layer 125, a second connection electrode CNE2, and a second via layer 127.

The first buffer layer 111 may be located on the substrate 110. The first buffer layer 111 may include an inorganic layer capable of preventing or reducing penetration of air or moisture. For example, the first buffer layer 111 may include a plurality of inorganic layers alternately stacked.

The thin film transistor TFT may be located on the first buffer layer 111, and may constitute a pixel circuit of each of the plurality of pixels. For example, the thin film transistor TFT may be a switching transistor or a driving transistor of the pixel circuit. The thin film transistor TFT may include an active layer ACT, a source electrode SE, a drain electrode DE, and a gate electrode GE.

The active layer ACT may be located on the first buffer layer 111. The active layer ACT may overlap the gate electrode GE in the third direction (Z-axis direction), and may be insulated from the gate electrode GE by the gate insulating layer 113. In a part of the active layer ACT, a material of the active layer ACT may be made into a conductor to form the source electrode SE and the drain electrode DE.

The gate electrode GE may be located on the gate insulating layer 113. The gate electrode GE may overlap the active layer ACT with the gate insulating layer 113 interposed therebetween.

The gate insulating layer 113 may be located on the active layer ACT. The gate insulating layer 113 may cover the active layer ACT and the first buffer layer 111, and may insulate the active layer ACT from the gate electrode GE. The gate insulating layer 113 may include a contact hole through which the first connection electrode CNE1 passes.

The first interlayer insulating layer 121 may cover the gate electrode GE and the gate insulating layer 113. The first interlayer insulating layer 121 may include a contact hole through which the first connection electrode CNE1 passes. The contact hole of the first interlayer insulating layer 121 may be connected to the contact hole of the gate insulating layer 131 and the contact hole of the second interlayer insulating layer 123.

The capacitor electrode CPE may be located on the first interlayer insulating layer 121. The capacitor electrode CPE may overlap the gate electrode GE in the third direction (Z-axis direction). The capacitor electrode CPE and the gate electrode GE may form a capacitance.

The second interlayer insulating layer 123 may cover the capacitor electrode CPE and the first interlayer insulating layer 121. The second interlayer insulating layer 123 may include a contact hole through which the first connection electrode CNE1 passes. The contact hole of the second interlayer insulating layer 123 may be connected to the contact hole of the first interlayer insulating layer 121 and the contact hole of the gate insulating layer 113.

The first connection electrode CNE1 may be located on the second interlayer insulating layer 123. The first connection electrode CNE1 may electrically connect the drain electrode DE of the thin film transistor TFT to the second connection electrode CNE2. The first connection electrode CNE1 may be inserted into a contact hole provided in the first interlayer insulating layer 121, the second interlayer insulating layer 123, and the gate insulating layer 113 to be in contact with the drain electrode DE of the thin film transistor TFT.

The first via layer 125 may cover the first connection electrode CNE1 and the second interlayer insulating layer 123. The first via layer 125 may flatten the lower structure. The first via layer 125 may include a contact hole through which the second connection electrode CNE2 passes.

The second connection electrode CNE2 may be located on the first via layer 125. The second connection electrode CNE2 may be inserted into a contact hole formed in the first via layer 125 to be in contact with the first connection electrode CNE1. The second connection electrode CNE2 may electrically connect the first connection electrode CNE1 to first to third anode electrodes AE1, AE2, and AE3.

The second via layer 127 may cover the second connection electrode CNE2 and the first via layer 125. The second via layer 127 may include a contact hole through which the first to third anode electrodes AE1, AE2, and AE3 pass.

The display element layer 150 may be located on the second via layer 127. The display element layer 150 may include the light emitting element ED, the inorganic pixel defining layer 151, a residual pattern 153, and the bank layer 161.

The light emitting element ED according to some embodiments may include a first light emitting element ED1 located in a portion overlapping the first emission area EA1, a second light emitting element ED2 located in a portion overlapping the second emission area EA2, and a third light emitting element ED3 located in a portion overlapping the third emission area EA3. The first light emitting element ED1 may include the first anode electrode AE1, a first light emitting layer EL1, and a first cathode electrode CE1, the second light emitting element ED2 may include the second anode electrode AE2, a second light emitting layer EL2, and a second cathode electrode CE2, and the third light emitting element ED3 may include the third anode electrode AE3, a third light emitting layer EL3, and a third cathode electrode CE3. Each of the first to third light emitting elements ED1, ED2, and ED3 may emit light of different colors depending on the materials of the first to third light emitting layers EL1, EL2, and EL3.

For example, the first light emitting element ED1 may emit the red light of the first color, the second light emitting element ED2 may emit the green light of the second color, and the third light emitting element ED3 may emit the blue light of the third color.

The first to third anode electrodes AE1, AE2, and AE3 according to some embodiments may be located on the second via layer 127. The first to third anode electrodes AE1, AE2, and AE3 may be electrically connected to the drain electrode DE of the thin film transistor TFT through the first connection electrode CNE1 and the second connection electrode CNE2.

The first to third anode electrodes AE1, AE2, and AE3 may include the first anode electrode AE1 located in the first emission area EA1, the second anode electrode AE2 located in the second emission area EA2, and the third anode electrode AE3 located in the third emission area EA3. The first anode electrode AE1, the second anode electrode AE2, and the third anode electrode AE3 may be located to be spaced apart from each other on the second via layer 127.

According to some embodiments, the first to third anode electrodes AE1, AE2, and AE3 may have a stacked structure formed by stacking a material layer having a high work function, such as indium tin oxide (ITO), indium zinc oxide (IZO), zinc oxide (ZnO) and indium oxide (In2O3), and a reflective material layer such as silver (Ag), magnesium (Mg), aluminum (AI), platinum (Pt), lead (Pb), palladium (Pd), gold (Au), nickel (Ni), neodymium (Nd), iridium (Ir), chromium (Cr), lithium (Li), calcium (Ca), or a mixture thereof. For example, the first to third anode electrodes AE1, AE2, and AE3 may have a multilayer structure of ITO/Mg, ITO/MgF, ITO/Ag, and ITO/Ag/ITO, but are not limited thereto.

The inorganic pixel defining layer 151 may be positioned on the second via layer 127 and the first to third anode electrodes AE1, AE2, and AE3. The inorganic pixel defining layer 151 may be positioned in a portion overlapping the non-emission area NLA.

The inorganic pixel defining layer 151 according to some embodiments may define the first opening OP1 overlapping the first to third emission areas EA1, EA2, and EA3. The inorganic pixel defining layer 151 may be located entirely on the second via layer 127 and may expose a portion of the first to third anode electrodes AE1, AE2, and AE3. In other words, the inorganic pixel defining layer 151 may expose the first to third anode electrodes AE1, AE2, and AE3 in a portion overlapping the first opening OP1.

The inorganic pixel defining layer 151 may include an inorganic insulating material. For example, the inorganic pixel defining layer 151 may include aluminum oxide, titanium oxide, tantalum oxide, hafnium oxide, zinc oxide, silicon oxide, silicon nitride, and silicon oxynitride.

The bank layer 161 may be positioned on the inorganic pixel defining layer 151. The bank layer 161 may define the second opening OP2 that defines the first to third emission areas EA1, EA2, and EA3, and the light emitting elements ED according to some embodiments may be arranged to overlap the second opening OP2.

The bank layer 161 according to some embodiments may include a conductive metal material. For example, the bank layer 161 may include at least one metal selected from the group consisting of molybdenum (Mo), aluminum (AI), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W) and copper (Cu).

The first to third light emitting layers EL1, EL2, and EL3 according to some embodiments may be located on the first to third anode electrodes AE1, AE2, and AE3. The first to third light emitting layers EL1, EL2, and EL3 may be organic light emitting layers made of an organic material, and may be formed on the first to third anode electrodes AE1, AE2, and AE3, respectively, by the deposition process. For the first to third light emitting layers EL1, EL2, and EL3, when the thin film transistor TFT applies a voltage (e.g., a set or predetermined voltage) to the first to third anode electrodes AE1, AE2, and AE3, and the first to third cathode electrodes CE1, CE2, and CE3 receive a common voltage or a cathode voltage, each of holes and electrons may move to the first to third light emitting layers EL1, EL2, and EL3 through the hole transport layer and the electron transport layer, and the holes and the electrons may be coupled with each other in the first to third light emitting layers EL1, EL2, and EL3 to emit light.

The first to third light emitting layers EL1, EL2, and EL3 may include the first light emitting layer EL1, the second light emitting layer EL2, and the third light emitting layer EL3 located in the respective emission areas EA1, EA2, and EA3. For example, the first light emitting layer EL1 may be the light emitting layer emitting red light of the first color, the second light emitting layer EL2 may be the light emitting layer emitting green light of the second color, and the third light emitting layer EL3 may be the light emitting layer emitting blue light of the third color, but the present disclosure is not limited thereto.

The first to third anode electrodes AE1, AE2, and AE3 and the inorganic pixel defining layer 151 according to some embodiments may be spaced apart from each other in the third direction (Z-axis direction). The residual pattern 153 may be positioned in a portion in which the first to third anode electrodes AE1, AE2, and AE3 are separated from the inorganic pixel defining layer 151. The residual pattern 153 will be described later.

The first to third cathode electrodes CE1, CE2, and CE3 may be located on the first to third light emitting layers EL1, EL2, and EL3. The first to third cathode electrodes CE1, CE2, and CE3 may include a transparent conductive material, so that light generated in the first to third light emitting layers EL1, EL2, and EL3 may be emitted. The first to third cathode electrodes CE1, CE2, and CE3 may receive a common voltage or a low potential voltage. When the first to third anode electrodes AE1, AE2, and AE3 receive a voltage corresponding to a data voltage, and the first to third cathode electrodes CE1, CE2, and CE3 receive a low potential voltage, a potential difference is formed between the first to third anode electrodes AE1, AE2, and AE3 and the first to third cathode electrodes CE1, CE2, and CE3, so that the first to third light emitting layers EL1, EL2, and EL3 may emit light.

According to some embodiments, the first to third cathode electrodes CE1, CE2, and CE3 may include a material layer having a low work function, such as Li, Ca, LiF/Ca, LiF/Al, Al, Mg, Ag, Pt, Pd, Ni, Au Nd, Ir, Cr, BaF, Ba or a compound or mixture thereof (e.g., a mixture of Ag and Mg). The first to third cathode electrodes CE1, CE2, and CE3 may further include a transparent metal oxide layer located on the material layer having a low work function.

The first to third cathode electrodes CE1, CE2, and CE3 may include the first cathode electrode CE1, the second cathode electrode CE2, and the third cathode electrode CE3 located in the respective emission areas EA1, EA2, and EA3. The first cathode electrode CE1 may be located on the first light emitting layer EL1 in the first emission area EA1, the second cathode electrode CE2 may be located on the second light emitting layer EL2 in the second emission area EA2, and the third cathode electrode CE3 may be located on the third light emitting layer EL3 in the third emission area EA3.

The first to third cathode electrodes CE1, CE2, and CE3 included according to some embodiments may be spaced apart from each other while overlapping the first to third emission areas EA1, EA2, and EA3, respectively. In other words, the first to third cathode electrodes CE1, CE2, and CE3 included according to some embodiments may not be directly connected, but may be electrically connected through the bank layer 161.

The thin film encapsulation layer 170 may be positioned on the display element layer 150. The thin film encapsulation layer 170 according to some embodiments may include a first encapsulation layer 171, a second encapsulation layer 173, and a third encapsulation layer 175 that are sequentially stacked.

The first encapsulation layer 171 may be positioned on the bank layer 161 and the first to third cathode electrodes CE1, CE2, and CE3, and the first encapsulation layer 171 may be in contact with the bank layer 161 and the first to third cathode electrodes CE1, CE2, and CE3. The first encapsulation layer 171 may cover the profile formed by the bank layer 161 and the first to third cathode electrodes CE1, CE2, and CE3. Accordingly, the first encapsulation layer 171 may have a stepped portion.

The first encapsulation layer 171 may include a first inorganic layer 171-1, a second inorganic layer 171-2, and a third inorganic layer 171-3 that are positioned to overlap the first to third emission area EA1, EA2, and EA3, respectively. The first inorganic layer 171-1, the second inorganic layer 171-2, and the third inorganic layer 171-3 may be spaced apart from each other in the first direction (X-axis direction) with the bank layer 161 interposed therebetween. In addition, a cavity may be formed between the first inorganic layer 171-1, the second inorganic layer 171-2, and the third inorganic layer 171-3 according to some embodiments and the bank layer 161 in the third direction (Z-axis direction).

In the drawing, the first to third inorganic layers 171-1, 171-2, and 171-3 are illustrated as being formed on the same layer, but the first to third inorganic layers 171-1, 171-2, and 171-3 may be formed in different processes, respectively. According to some embodiments, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The fabricating process will be explained later.

The first encapsulation layer 171 may include an inorganic material, for example, aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may be positioned on the first encapsulation layer 171. The second encapsulation layer 173 may flatten the stepped portion formed by the first encapsulation layer 171 in a portion overlapping the first to third emission areas EA1, EA2, and EA3, and the second encapsulation layer 173 may fill the cavity formed between the first encapsulation layer 171 and the bank layer 161 in a portion overlapping the first to third emission areas EA1, EA2, and EA3 and the non-emission area NLA.

The second encapsulation layer 173 may include a polymer-based material. Examples of the polymer-based material may include acrylic resin, epoxy resin, polyimide, polyethylene and the like. For example, the second encapsulation layer 173 may include an acrylic resin, for example, polymethyl methacrylate, polyacrylic acid, or the like. The second encapsulation layer 173 may be formed by curing a monomer or applying a polymer.

The third encapsulation layer 175 may be positioned on the second encapsulation layer 173 and may completely cover the second encapsulation layer 173. The third encapsulation layer 175 may include an inorganic material, and may include the same material as the first encapsulation layer 171. Redundant descriptions will be omitted.

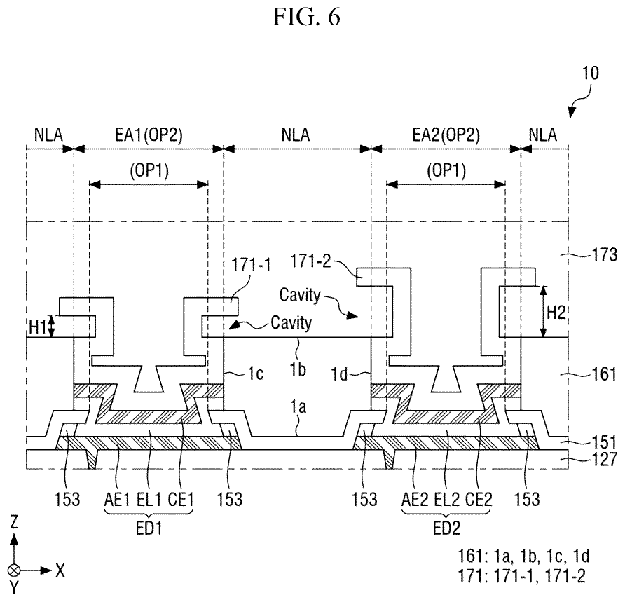

FIG. 6 is an enlarged schematic cross-sectional view of the first emission area and the second emission area in FIG. 5.

Referring to FIG. 6, the first emission area EA1 according to some embodiments may be positioned between the non-emission areas NLA located on both sides in the first direction (X-axis direction). In addition, the second emission area EA2 according to some embodiments may be spaced apart from the first emission area EA1 with the non-emission area NLA interposed therebetween.

The inorganic pixel defining layer 151 according to some embodiments may be located in a portion overlapping the non-emission area NLA, and the first light emitting element ED1 and the second light emitting element ED2 according to some embodiments may be separated and insulated by the inorganic pixel defining layer 151. The inorganic pixel defining layer 151 may include a stepped portion depending on the profile of the underlying structure.

The bank layer 161 according to some embodiments may be located in a portion overlapping the non-emission area NLA and may be located on and in contact with the inorganic pixel defining layer 151. The bank layer 161 according to some embodiments may electrically connect the first cathode electrode CE1 and the second cathode electrode CE2 that are arranged to be spaced apart by including a conductive material. As described above, the inorganic pixel defining layer 151 may define the first opening OP1, the bank layer 161 may define the second opening OP2, and in cross-sectional view, the first opening OP1 may be located inside the second opening OP2.

According to some embodiments, the bank layer 161 may include a first surface 1a, a second surface 1b, a first side surface 1c, and a second side surface 1d.

According to some embodiments, the first surface 1a of the bank layer 161 may be one surface facing the inorganic pixel defining layer 151. The first surface 1a of the bank layer 161 may be in contact with the inorganic pixel defining layer 151 and may include a stepped portion formed by the inorganic pixel defining layer 151. The second surface 1b of the bank layer 161 may be one surface opposite to the first surface 1a. The second surface 1b may not include a stepped portion and may be one surface in contact with the second encapsulation layer 173.

According to some embodiments, the first side surface 1c of the bank layer 161 may be one surface facing the first emission area EA1 and may be one surface connecting the first surface 1a to the second surface 1b. The first side surface 1c may include a structure that is depressed in the first direction (X-axis direction) more toward the non-emission area NLA than the inorganic pixel defining layer 151. The first side surface 1c according to some embodiments may be in contact with the first light emitting layer EL1, the first cathode electrode CE1, and the first inorganic layer 171-1.

The second side surface 1d of the bank layer 161 may be one surface facing the second emission area EA2 and may be one surface connecting the first surface 1a to the second surface 1b. The second side surface 1d may include a structure that is depressed in the first direction (X-axis direction) more toward the non-emission area NLA than the inorganic pixel defining layer 151. In addition, the second side surface 1d may be in contact with the second light emitting layer EL2, the second cathode electrode CE2, and the second inorganic layer 171-2.

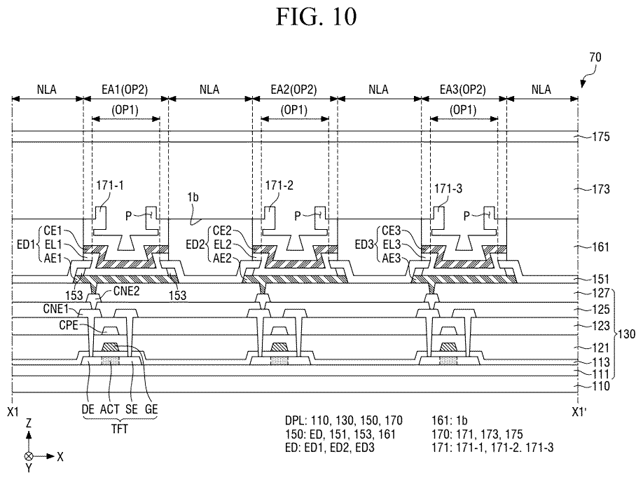

The display device 10 according to some embodiments may include a sacrificial layer SFL (see FIG. 10) during the fabricating process. The sacrificial layer SFL may be located between the inorganic pixel defining layer 151 and the first anode electrode AE1 and between the inorganic pixel defining layer 151 and the second anode electrode AE2, respectively, and then a portion thereof may be removed in a subsequent wet etching process. At this time, a part of the sacrificial layer SFL that has not been removed may remain as the residual pattern 153 between the inorganic pixel defining layer 151 and the first anode electrode AE1 and between the inorganic pixel defining layer 151 and the second anode electrode AE2, respectively.

The residual pattern 153 may include an oxide semiconductor. For example, the residual pattern 153 may include at least one of indium-gallium-zinc oxide (IGZO), zinc-tin oxide (ZTO), or indium-tin oxide (ITO)

The first light emitting layer EL1 according to some embodiments may be located on the first anode electrode AE1 in a portion overlapping the first emission area EA1, may be in contact with the first side surface 1c of the bank layer 161, and may be completely covered by the first cathode electrode CE1. In addition, the first light emitting layer EL1 according to some embodiments may be in contact with the residual pattern 153 on both sides of the first direction (X-axis direction).

The second light emitting layer EL2 according to some embodiments may be located on the second anode electrode AE2 in a portion overlapping the second emission area EA2, may be in contact with the second side surface 1d of the bank layer 161, and may be completely covered by the second cathode electrode CE2. In addition, the second light emitting layer EL2 according to some embodiments may be in contact with the residual pattern 153 on both sides of the first direction (X-axis direction).

The first cathode electrode CE1 according to some embodiments may be located on the first light emitting layer EL1 in a portion overlapping the first emission area EA1, and the first cathode electrode CE1 may completely cover the first light emitting layer EL1. Further, the first cathode electrode CE1 may be in contact with the first side surface 1c of the bank layer 161 within the second opening OP2, and may be completely covered by the first inorganic layer 171-1 in a portion overlapping the first emission area EA1.

The second cathode electrode CE2 according to some embodiments may be located on the second light emitting layer EL2 in a portion overlapping the second emission area EA2, and the second cathode electrode CE2 may completely cover the second light emitting layer EL2. Further, the second cathode electrode CE2 may be in contact with the second side surface 1d of the bank layer 161, and may be completely covered by the second inorganic layer 171-2 in a portion overlapping the second emission area EA2.

The first encapsulation layer 171 according to some embodiments may include the first inorganic layer 171-1 and the second inorganic layer 171-2. The first inorganic layer 171-1 and the second inorganic layer 171-2 may be spaced apart from each other in a portion overlapping the non-emission area NLA.

The first inorganic layer 171-1 according to some embodiments may completely cover the first cathode electrode CE1 in a portion overlapping the first emission area EA1 and may be in contact with the first cathode electrode CE1. Further, the first inorganic layer 171-1 may cover the first side surface 1c of the bank layer 161 and may be in contact with the first side surface 1c of the bank layer 161. In extension to this, the first inorganic layer 171-1 according to some embodiments may completely cover the cavity in a portion overlapping the first emission area EA1. In other words, the cavity may be completely surrounded by the first inorganic layer 171-1 in the portion overlapping the first emission area EA1.

In addition, the first inorganic layer 171-1 according to some embodiments may overlap the bank layer 161 in a portion overlapping the non-emission area NLA, and may not be in contact with the second surface 1b of the bank layer 161. In other words, the first inorganic layer 171-1 may be spaced apart from the second surface 1b of the bank layer 161 in the third direction (Z-axis direction) with a cavity interposed therebetween.

The second inorganic layer 171-2 according to some embodiments may completely cover the second cathode electrode CE2 in a portion overlapping the second emission area EA2 and may be in contact with the second cathode electrode CE2. Further, the second inorganic layer 171-2 may completely cover the second side surface 1d of the bank layer 161 and may be in contact with the second side surface 1d. In extension to this, the second inorganic layer 171-2 according to some embodiments may completely cover the cavity in a portion overlapping the second emission area EA2. In other words, the cavity may be completely surrounded by the second inorganic layer 171-2 in the portion overlapping the second emission area EA2.

In addition, the second inorganic layer 171-2 according to some embodiments may overlap the bank layer 161 in a portion overlapping the non-emission area NLA, and may not be in contact with the second surface 1b of the bank layer 161. In other words, the second inorganic layer 171-2 may be spaced apart from the second surface 1b of the bank layer 161 in the third direction (Z-axis direction) with a cavity interposed therebetween.

During the fabricating process, the display device 10 according to some embodiments may include a process in which a photoresist, the first light emitting layer EL1, and the first cathode electrode CE1 are located entirely on the second surface 1b of the bank layer 161 and are covered by the first inorganic layer 171-1. However, the photoresist, the first light emitting layer EL1, and the first cathode electrode CE1 located on the second surface 1b may be removed through a subsequent etching process. As a result, a cavity may be formed between the second surface 1b of the bank layer 161 and the first inorganic layer 171-1.

In the following process, the display device 10 according to some embodiments may include a process in which a photoresist, the second light emitting layer EL2, and the second cathode electrode CE2 are located entirely on the first inorganic layer 171-1 and the second surface 1b and are covered by the second inorganic layer 171-2. However, a portion of the photoresist, the second light emitting layer EL2, and the second cathode electrode CE2 located on the first inorganic layer 171-1 and the second surface 1b may be removed by a subsequent etching process, and as a result, a cavity may be formed between the second surface 1b of the bank layer 161 and the second inorganic layer 171-2. The fabricating process will be explained later.

According to some embodiments, the height of the cavity formed between the first inorganic layer 171-1 and the second surface 1b of the bank layer 161 may be defined as a first height H1, and the height of the cavity formed between the second inorganic layer 171-2 and the second surface 1b of the bank layer 161 may be defined as a second height H2.

According to some embodiments, the first height H1 and the second height H2 may be different from each other. For example, the second height H2 may be greater than the first height H1. As described above, this may be caused due to the fact that during the fabricating process of the display device 10, the cavity formed to overlap the second inorganic layer 171-2 is formed in a subsequent process as compared with the cavity formed to overlap the first inorganic layer 171-1.

The second encapsulation layer 173 according to some embodiments may be located on the first encapsulation layer 171. As described above, the second encapsulation layer 173 may flatten the first inorganic layer 171-1 and the second inorganic layer 171-2 in a portion overlapping the first emission area EA1 and the second emission area EA2, and the second encapsulation layer 173 may fill the inside of a cavity overlapping the first inorganic layer 171-1 and the inside of a cavity overlapping the second inorganic layer 171-2 in a portion overlapping the non-emission area NLA. In other words, the second encapsulation layer 173 may be located between the second surface 1b of the bank layer 161 and the first encapsulation layer 171.

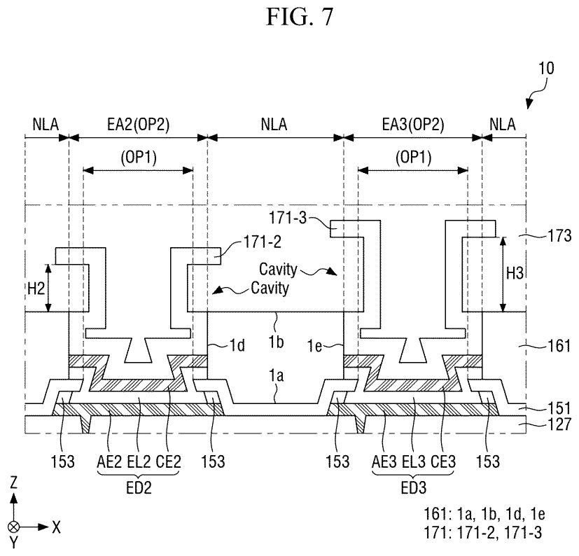

FIG. 7 is an enlarged schematic cross-sectional view of the second emission area and the third emission area in FIG. 5.

Referring to FIG. 7, the second emission area EA2 according to some embodiments may be positioned between the non-emission areas NLA located on both sides in the first direction (X-axis direction). In addition, the third emission area EA3 according to some embodiments may be spaced apart from the first emission area EA1 with the non-emission area NLA interposed therebetween.

The inorganic pixel defining layer 151 according to some embodiments may be located in a portion overlapping the non-emission area NLA, and the second light emitting element ED2 and the third light emitting element ED3 according to some embodiments may be separated and insulated by the inorganic pixel defining layer 151. Other redundant descriptions are omitted.

The bank layer 161 according to some embodiments may electrically connect the second cathode electrode CE2 and the third cathode electrode CE3 that are arranged to be spaced apart by including a conductive material.

According to some embodiments, the bank layer 161 according to some embodiments may include the first surface 1a, the second surface 1b, the second side surface 1d, and a third side surface 1e. The first surface 1a, the second surface 1b, and the second side surface 1d of the bank layer 161 have already been described above and will be omitted.

The third side surface 1e of the bank layer 161 may be one surface facing the third emission area EA3, may be one surface connecting the first surface 1a to the second surface 1b, and may be opposite to the second side surface 1d. The third side surface 1e may include a structure that is depressed in the first direction (X-axis direction) more toward the non-emission area NLA than the inorganic pixel defining layer 151. In addition, the third side surface 1e may be in contact with the third light emitting layer EL3, the third cathode electrode CE3, and the third inorganic layer 171-3.

In the fabricating process of forming the light emitting element ED according to some embodiments, the sacrificial layer SFL may be located between the inorganic pixel defining layer 151 and the third anode electrode AE3, and then a portion thereof may be removed by a subsequent wet etching process. At this time, a portion of the sacrificial layer SFL that has not been removed may remain as the residual pattern 153 between the inorganic pixel defining layer 151 and the third anode electrode AE3.

The third light emitting layer EL3 according to some embodiments may be located on the third anode electrode AE3 in a portion overlapping the third emission area EA3, may be in contact with the third side surface 1e of the bank layer 161, and may be completely covered by the third cathode electrode CE3. The third light emitting layer EL3 according to some embodiments may be in contact with the residual pattern 153 on both sides of the third direction (X-axis direction).

The third cathode electrode CE3 according to some embodiments may be located on the third light emitting layer EL3 in a portion overlapping the third emission area EA3, may be in contact with the third side surface 1e of the bank layer 161, and may be completely covered by the third inorganic layer 171-3.

The third inorganic layer 171-3 according to some embodiments may completely cover the third cathode electrode CE3 in a portion overlapping the third emission area EA3, and may be in contact with the third cathode electrode CE3. Further, the third inorganic layer 171-3 may completely cover the third side surface 1e of the bank layer 161, and may be in contact with the third side surface 1e of the bank layer 161. In extension to this, the third inorganic layer 171-3 according to some embodiments may completely cover the cavity in a portion overlapping the third emission area EA3. In other words, the cavity may be completely surrounded by the third inorganic layer 171-3 in the portion overlapping the third emission area EA3.

In addition, the third inorganic layer 171-3 according to some embodiments may overlap the bank layer 161 in a portion overlapping the non-emission area NLA, and may not be in contact with the second surface 1b of the bank layer 161. In other words, the third inorganic layer 171-3 may be spaced apart from the second surface 1b of the bank layer 161 in the third direction (Z-axis direction) with a cavity interposed therebetween. Other redundant descriptions will be omitted.

During the fabricating process, as a subsequent process after the process of forming a cavity between the second surface 1b of the bank layer 161 and the second inorganic layer 171-2, the display device 10 according to some embodiments may include a process in which a photoresist, the third light emitting layer EL3, and the third cathode electrode CE3 are formed entirely on the second inorganic layer 171-2 and the second surface 1b, and are covered by the third inorganic layer 171-3. However, a portion of the photoresist, the third light emitting layer EL3, and the third cathode electrode CE3 located on the second inorganic layer 171-2 and the second surface 1b may be removed by a subsequent etching process, and as a result, a cavity may be formed between the second surface 1b of the bank layer 161 and the third inorganic layer 171-3.

In some embodiments, the height of the cavity formed between the third inorganic layer 171-3 and the second surface 1b of the bank layer 161 may be defined as a third height H3, and the second height H2 and the third height H3 may be different from each other. For example, the third height H3 may be greater than the second height H2. As described above, this may be caused due to the fact that during the fabricating process of the display device 10, the cavity formed to overlap the third inorganic layer 171-3 is formed in a subsequent process as compared with the cavity formed to overlap the second inorganic layer 171-2.

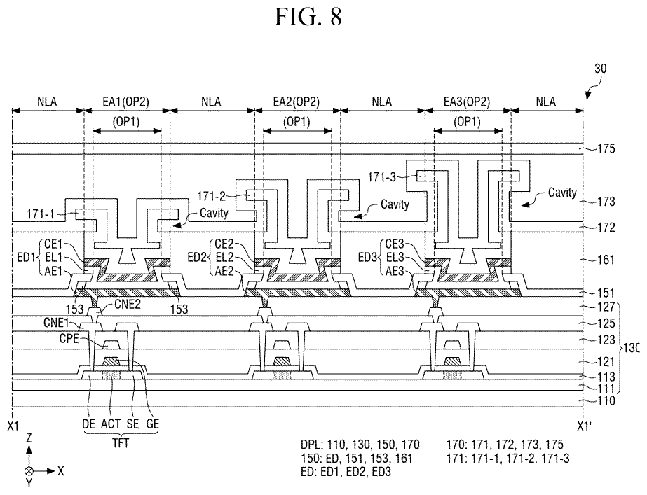

FIG. 8 is a schematic cross-sectional view of a display layer according to some embodiments taken along line X1-X1′ of FIG. 4, according to some embodiments.

Referring to FIG. 8, a display device 30 according to some embodiments may be different from the display device 10 according to some embodiments in that an auxiliary inorganic layer 172 is included. In other words, the thin film encapsulation layer 170 according to some embodiments may include the first encapsulation layer 171, the auxiliary inorganic layer 172, the second encapsulation layer 173, and the third encapsulation layer 175.

The auxiliary inorganic layer 172 included in the display device 30 according to some embodiments may entirely cover the first to third inorganic layers 171-1, 171-2, and 171-3 arranged to be spaced apart from each other in the portions respectively overlapping the first to third emission areas EA1, EA2, and EA3. That is, the auxiliary inorganic layer 172 may be arranged entirely to overlap the first to third emission areas EA1, EA2, and EA3 and the non-emission area NLA. The auxiliary inorganic layer 172 according to some embodiments may cover the profile formed by the first to third inorganic layers 171-1, 171-2, and 171-3.

Specifically, the auxiliary inorganic layer 172 may include a stepped portion in a portion overlapping the first to third emission areas EA1, EA2, and EA3, may form a cavity in a portion overlapping the first to third emission areas EA1, EA2, and EA3 and the non-emission area NLA, and may cover the first to third inorganic layers 171-1, 171-2, and 171-3. However, the present disclosure is not limited thereto, and depending on the structure formed by the first to third inorganic layers 171-1, 171-2, and 171-3, the auxiliary inorganic layer 172 may cover the first to third inorganic layers 171-1, 171-2, and 171-3 without forming a cavity.

The auxiliary inorganic layer 172 according to some embodiments may include an inorganic material. For example, the auxiliary inorganic layer 172 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O). Other redundant descriptions will be omitted.

The second encapsulation layer 173 according to some embodiments may be located on the auxiliary inorganic layer 172 and may fill the stepped portion and the cavity formed by the auxiliary inorganic layer 172. Redundant descriptions will be omitted.

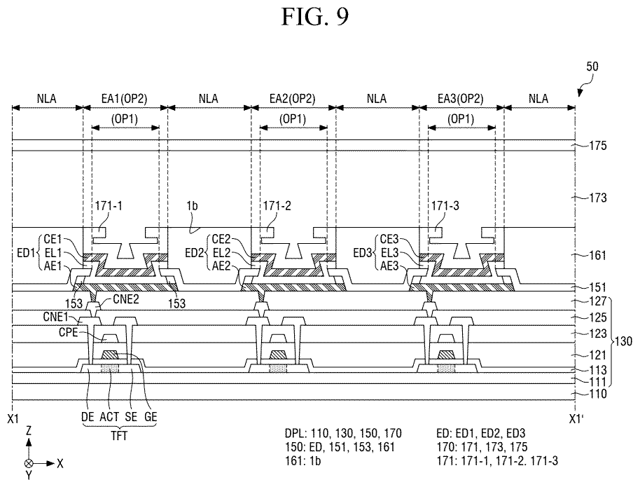

FIG. 9 is a schematic cross-sectional view of a display layer according to some embodiments taken along line X1-X1′ of FIG. 4, according to some embodiments.

Referring to FIG. 9, a display device 50 according to some embodiments may be different from the display device 10 according to some embodiments in that the first encapsulation layer 171 does not overlap the non-emission area NLA and is arranged to overlap the first to third emission areas EA1, EA2, and EA3.

The first encapsulation layer 171 included in the display device 50 according

to some embodiments may include the first to third inorganic layers 171-1, 171-2, and 171-3 located in the portion overlapping the first to third emission areas EA1, EA2, and EA3. The first to third inorganic layers 171-1, 171-2, and 171-3 according to some embodiments may completely cover the first to third light emitting elements ED1, ED2, and ED3 in the portion overlapping the first to third emission areas EA1, EA2, and EA3, and may completely cover both side surfaces of the bank layer 161 facing the first to third emission areas EA1, EA2, and EA3. The first to third inorganic layers 171-1, 171-2, and 171-3 may include the stepped portion as they cover the profile formed by the first to third light emitting elements ED1, ED2, and ED3 and the bank layer 161.

The first to third inorganic layers 171-1, 171-2, and 171-3 according to some embodiments may not overlap the non-emission area NLA. In other words, the first to third inorganic layers 171-1, 171-2, and 171-3 according to some embodiments may not overlap the inorganic pixel defining layer 151 and the bank layer 161 in the third direction (Z-axis direction). In the fabricating process included in the display device 50 according to some embodiments, this may be formed as the portion of the first to third inorganic layers 171-1, 171-2, and 171-3 are etched through a dry etching process performed after the photo pattern.

The second encapsulation layer 173 according to some embodiments may fill the stepped portion of the first to third inorganic layers 171-1, 171-2, and 171-3 in the portion overlapping the first to third emission areas EA1, EA2, and EA3. As a result, the stepped portion included in the first to third inorganic layers 171-1, 171-2, and 171-3 according to some embodiments may be flattened.

The second surface 1b included in the bank layer 161 according to some embodiments may be entirely covered by the second encapsulation layer 173 in a portion overlapping the non-emission area NLA. Other overlapping descriptions of structures and features will be omitted.

FIG. 10 is a schematic cross-sectional view of the display layer according to some embodiments taken along line X1-X1′ of FIG. 4, according to some embodiments.

Referring to FIG. 10, a display device 70 according to some embodiments may be different from the display device 10 according to some embodiments in that the first encapsulation layer 171 does not overlap the non-emission area NLA and includes a protrusion P in a portion overlapping the first to third emission areas EA1, EA2, and EA3.

The first encapsulation layer 171 included in the display device 70 according to some embodiments may include the first to third inorganic layers 171-1, 171-2, and 171-3 located in the portion overlapping the first to third emission areas EA1, EA2, and EA3. The first to third inorganic layers 171-1, 171-2, and 171-3 may completely cover the first to third light emitting elements ED1, ED2, and ED3 in the portion overlapping the first to third emission areas EA1, EA2, and EA3, and may completely cover both side surfaces of the bank layer 161 facing the first to third emission areas EA1, EA2, and EA3. The first to third inorganic layers 171-1, 171-2, and 171-3 may include the stepped portion as they cover the profile formed by the first to third light emitting elements ED1, ED2, and ED3 and the bank layer 161.

In addition, the first to third inorganic layers 171-1, 171-2, and 171-3 according to some embodiments may include the protrusion P in a portion overlapping the first to third emission areas EA1, EA2, and EA3. The protrusion P may be a portion that protrudes toward one side in the third direction (Z-axis direction) as compared with the second surface 1b of the bank layer 161. In the fabricating process included in the display device 70 according to some embodiments, this may be formed as the portion of the first to third inorganic layers 171-1, 171-2, and 171-3 are etched through a dry etching process performed after the photo pattern.

The first to third inorganic layers 171-1, 171-2, and 171-3 according to some embodiments may not overlap the non-emission area NLA. In other words, the first to third inorganic layers 171-1, 171-2, and 171-3 according to some embodiments may not overlap the inorganic pixel defining layer 151 and the bank layer 161 in the third direction (Z-axis direction).

The second encapsulation layer 173 according to some embodiments may fill the stepped portion of the first to third inorganic layers 171-1, 171-2, and 171-3 in the portion overlapping the first to third emission areas EA1, EA2, and EA3, and may completely cover the protrusion P included in the first to third inorganic layers 171-1, 171-2, and 171-3. Other overlapping descriptions of structures and features will be omitted.

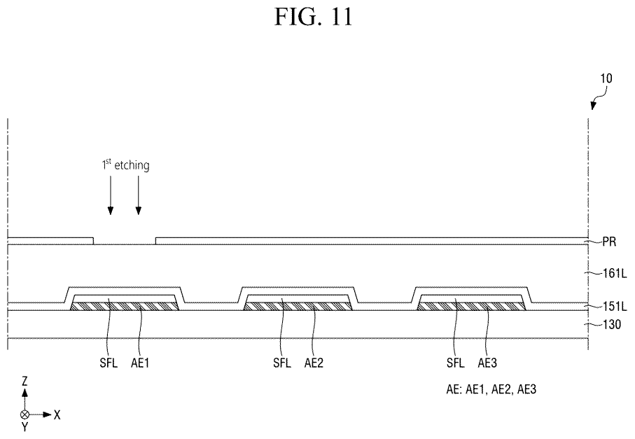

FIGS. 11 to 19 are cross-sectional views illustrating a schematic fabricating method of the display device 10 of FIG. 5. Hereinafter, the fabricating process of the display device 10 will be described with respect to the formation order of each layer.

Referring to FIG. 11, a plurality of first to third anode electrodes AE1, AE2, and AE3 are formed on the thin film transistor layer 130. The first to third anode electrodes AE1, AE2, and AE3 may be arranged to be spaced apart from each other on the thin film transistor layer 130. According to some embodiments, the thin film transistor layer 130 may be located on the substrate 110, and the structure of the thin film transistor layer 130 is the same as that described above with reference to FIG. 5. A detailed description thereof will be omitted.

Subsequently, the sacrificial layer SFL may be located on each of the first to third anode electrodes AE1, AE2, and AE3. The sacrificial layer SFL may be located on each of the first to third anode electrodes AE1, AE2, and AE3, and then a portion thereof may be removed in a subsequent process to form a space in which the first to third light emitting layers EL1, EL2, and EL3 are located. The sacrificial layer SFL may help prevent or reduce instances of the top surfaces of the first to third anode electrodes AE1, AE2, and AE3 coming into contact with the inorganic pixel defining layer 151. The sacrificial layer SFL may include an oxide semiconductor, and as a result, may have an etching rate different from that of a pixel defining material layer 151L and a bank material layer 161L.

The pixel defining material layer 151L and the bank material layer 161L may be located on the plurality of first to third anode electrodes AE1, AE2, and AE3 and the sacrificial layer SFL. The pixel defining material layer 151L may be arranged to entirely cover the sacrificial layer SFL and the thin film transistor layer 130, and the bank material layer 161L may be arranged to entirely cover the pixel defining material layer 151L.

Next, a first photoresist PR1 is formed on the bank material layer 161L. The first photoresist PR1 may be formed to expose a portion overlapping the first anode electrode AE1. Subsequently, a first etching process (1^{st} etching) is performed to etch a portion of the pixel defining material layer 151L and the bank material layer 161L by using the first photoresist PR1 as a mask. As an example, the first etching process may be performed as a dry etching process.

Through the present process, the bank material layer 161L and the pixel defining material layer 151L overlapping the first anode electrode AE1 may be etched, and as a result, a portion of the sacrificial layer SFL positioned on the first anode electrode AE1 may be exposed.

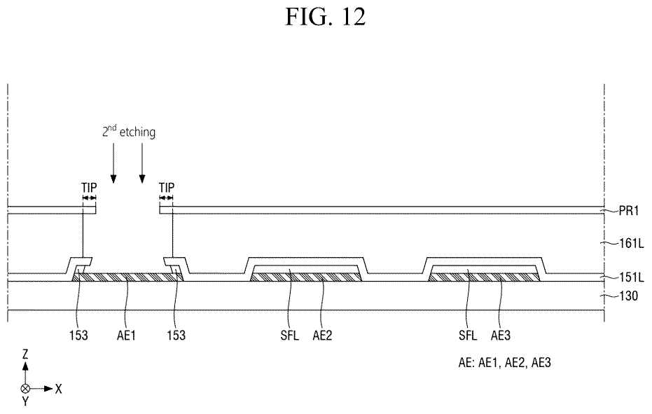

Next, referring to FIG. 12, a second etching process (2^{nd} etching) is performed using the first photoresist PR1 as a mask. For example, the second etching process (2^{nd} etching) may be performed as a wet etching process.

In the present process, the side surface of the bank material layer 161L may be depressed in the first direction (X-axis direction) as compared with the pixel defining material layer 151L, and as a result, the first photoresist PR1 may include a tip TIP protruding more than the bank material layer 161L. At the same time, in the present process, a portion of the sacrificial layer SFL arranged to overlap the first anode electrode AE1 may be removed. However, the sacrificial layer SFL may not be completely removed and may remain as the partial residual pattern 153 in the space between the pixel defining material layer 151L and the first anode electrode AE1.

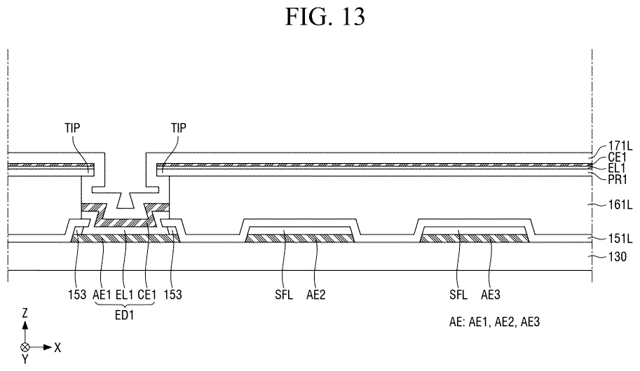

Next, referring to FIG. 13, the first light emitting layer EL1 and the first cathode electrode CE1 may be deposited on the first anode electrode AE1. The first light emitting layer EL1 according to some embodiments may be formed through a thermal evaporation process. The first light emitting layer EL1 may be formed on the first anode electrode AE1 without a mask because the first photoresist PR1 includes the tip TIP protruding more than the bank material layer 161L. However, the deposition process to form the first light emitting layer EL1 may be performed by being tilted at an angle of 45° to 50° from the top surface of the first anode electrode AE1. As a result, the first light emitting layer EL1 may be formed to fill the separation space between the first anode electrode AE1 and the pixel defining material layer 151L, and the first light emitting layer EL1 may also be formed on a portion of the side surface of the bank material layer 161L that is covered by the protruding tip TIP of the first photoresist PR1.

In the present process, the first light emitting layer EL1 according to some embodiments may also be formed above the first photoresist PR1 overlapping the second anode electrode AE2 and the third anode electrode AE3. In the first light emitting layer EL1 positioned above the first photoresist PR1, as the first photoresist PR1 includes the tip TIP, the first light emitting layer EL1 on the first anode electrode AE1 may be formed by being disconnected without being connected.

The first cathode electrode CE1 according to some embodiments may be formed through a thermal evaporation process. The deposition process to form the first cathode electrode CE1 may be performed by being tilted at an angle of 30° or less from the top surface of the first anode electrode AE1. In other words, the deposition process for forming the first cathode electrode CE1 may be performed by being tilted at an angle relatively closer to a horizontal direction than the deposition process for forming the first light emitting layer EL1. As a result, the first cathode electrode CE1 may completely cover the first light emitting layer EL1, and may completely cover the first light emitting layer EL1 even on the side surface of the bank material layer 161L covered by the protruding tip TIP of the first photoresist PR1. Through the present process, the first light emitting element ED1 may be formed.

Next, a first encapsulation material layer 171L covering the first cathode electrode CE1 is formed entirely. A chemical vapor deposition (CVD) process may be performed on the first encapsulation material layer 171L, and the first encapsulation material layer 171L may form a uniform layer regardless of the stepped portion of the lower structure. For example, the first encapsulation material layer 171L may also cover the undercut area formed by the protruding tip TIP of the first photoresist PR1 and the bank material layer 161L.

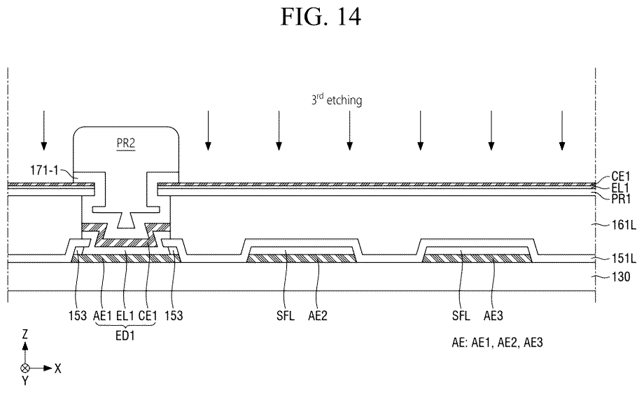

Referring to FIG. 14, a second photoresist PR2 is formed on a portion overlapping the first light emitting element ED1 and the periphery of the first light emitting element ED1, and a third etching process (3rd etching) is performed to etch a partial structure of an area excluding the first light emitting element ED1 and the peripheral portion of the first light emitting element ED1. As an example, the third etching process may be performed alternately between a wet process and a dry etching process. In other words, in the present process, the first light emitting layer EL1, the first cathode electrode CE1, and the first encapsulation material layer 171L in a portion in which the second photoresist PR2 is not formed may all be removed.

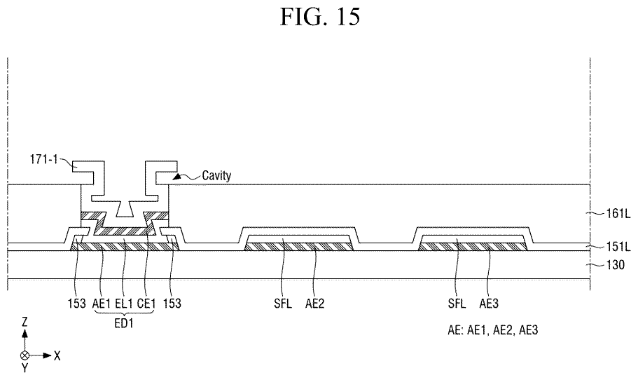

Referring to FIG. 15, the first light emitting element ED1 and the first inorganic layer 171-1 may be formed through the present process, and at the same time, a cavity may be formed between the first inorganic layer 171-1 and the bank material layer 161L in the third direction (Z-axis direction).

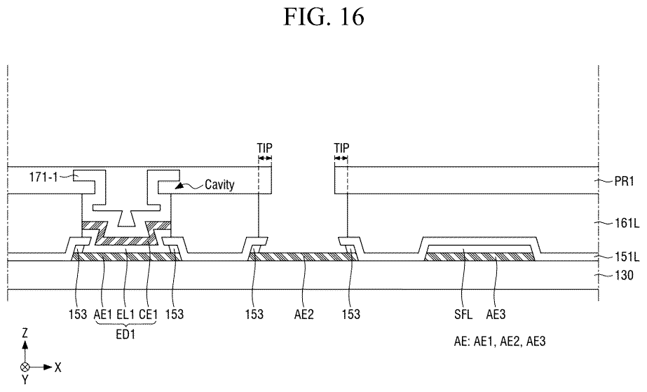

Next, referring to FIGS. 16 to 18, the above-described processes are repeated to form the second light emitting element ED2.

Specifically, the first photoresist PR1 having a thickness capable of covering the first inorganic layer 171-1 and a cavity overlapping the first inorganic layer 171-1 is formed on the bank material layer 161L. The first photoresist PR1 is formed to expose a portion of the second anode electrode AE2.

Next, the bank material layer 161L and the pixel defining material layer 151L overlapping the second anode electrode AE2 are etched through a dry etching process, and then a portion of the bank material layer 161L is etched through a wet etching process such that the first photoresist PR1 has the tip TIP. In other words, a portion of the bank material layer 161L is etched such that the bank material layer 161L may be depressed in the first direction (X-axis direction) as compared with the pixel defining material layer 151L.

At the same time, a portion of the sacrificial layer SFL located on the second anode electrode AE2 is removed to expose a portion of the second anode electrode AE2. In the present process, the sacrificial layer SFL may not be completely removed, and the partial residual pattern 153 may remain in the space between the pixel defining material layer 151L and the second anode electrode AE2.

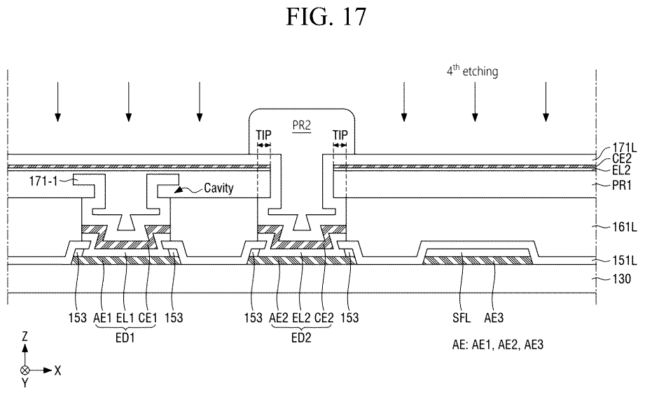

Next, referring to FIG. 17, the second light emitting layer EL2 and the second cathode electrode CE2 are deposited on the second anode electrode AE2. According to some embodiments, the second light emitting layer EL2 and the second cathode electrode CE2 may be deposited without a mask because the first photoresist PR1 includes the tip TIP. Accordingly, the second light emitting layer EL2 and the second cathode electrode CE2 may also be deposited on the first photoresist PR1. The second light emitting layer EL2 according to some embodiments may be in contact with the residual pattern 153.

Subsequently, after forming the second cathode electrode CE2 entirely on the first encapsulation material layer 171L, the second photoresist PR2 is formed on a portion overlapping the second anode electrode AE2 and the periphery of the second anode electrode AE2, and a partial structure of an area excluding a portion overlapping the second anode electrode AE2 and the periphery of the second anode electrode AE2 is etched. In other words, the second light emitting layer EL2, the second cathode electrode CE2, and the first encapsulation material layer 171L in a portion in which the second photoresist PR2 is not formed may all be removed.

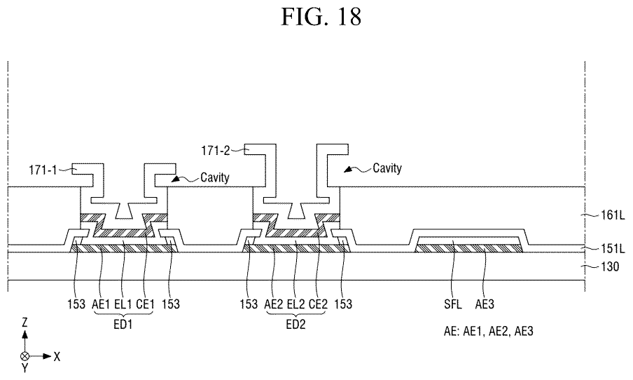

Referring to FIG. 18, the second light emitting element ED2 and the second inorganic layer 171-2 may be formed through the present process, and a cavity may be formed between the second inorganic layer 171-2 and the bank material layer 161L.

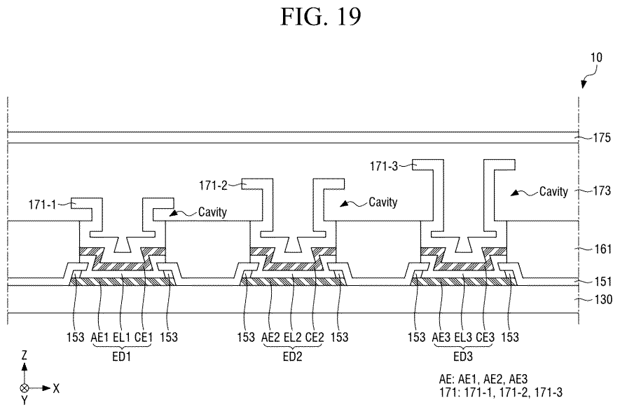

Referring to FIG. 19, the above-described process of forming the second light emitting element ED2 is repeated again to form the third light emitting element ED3. Through the present process, the third light emitting element ED3 and the third inorganic layer 171-3 may be formed, and a cavity may be formed between the third inorganic layer 171-3 and the bank layer 161. Through the present process, the first encapsulation material layer 171L may be in the form of the first to third inorganic layers 171-1, 171-2, and 171-3, the bank material layer 161L may be in the form of the bank layer 161, and the pixel defining material layer 151L may be in the form of the inorganic pixel defining layer 151.

As illustrated in the drawing, the height of the cavity formed to overlap the first inorganic layer 171-1 in the third direction (Z-axis direction), the height of the cavity formed to overlap the second inorganic layer 171-2, and the height of the cavity formed to overlap the third inorganic layer 171-3 may be formed differently. For example, the height of the cavity arranged to overlap the third inorganic layer 171-3 may be the highest, and the height of the cavity formed overlapping the first inorganic layer 171-1 may be the lowest. This may be caused because the first to third inorganic layers 171-1, 171-2, and 171-3 are not formed in the same process but are formed sequentially.

Next, the second encapsulation layer 173 is formed entirely to flatten the stepped portion included in the first encapsulation layer 171, and the third encapsulation layer 175 is formed entirely on the second encapsulation layer 173. The second encapsulation layer 173 may be formed to fill the cavity.

As described above, the display device 10 according to some embodiments uses the tip TIP included in the first photoresist PR1 during the fabricating process, so that the first to third light emitting elements ED1 and ED2, and ED3 may be formed without a mask. As a result, the display device 10 according to some embodiments may have high-resolution features and may be easily fabricated.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a substrate comprising an emission area and a non-emission area;
a first light emitting element on the emission area of the substrate;
a pixel defining layer on the non-emission area of the substrate and defining a first opening;
a bank layer on the pixel defining layer, defining a second opening, and containing a conductive material;
a first encapsulation layer on the first light emitting element and containing an inorganic material; and
a second encapsulation layer on the first encapsulation layer and containing an organic material,
wherein a cavity is formed between the first encapsulation layer and the bank layer in a direction perpendicular to the substrate,
the cavity overlaps the emission area and the non-emission area, and
the cavity is filled by the second encapsulation layer.

2. The display device of claim 1, further comprising a second light emitting element spaced apart from the first light emitting element with the bank layer interposed therebetween,
wherein the first light emitting element comprises:
a first anode electrode on the substrate;
a first light emitting layer on the first anode electrode; and
a first cathode electrode on the first light emitting layer, and
the second light emitting element comprises:
a second anode electrode spaced apart from the first anode electrode with the pixel defining layer interposed therebetween;
a second light emitting layer on the second anode electrode; and
a second cathode electrode on the second light emitting layer.

3. The display device of claim 2, wherein the bank layer comprises:
a first side surface in contact with the first cathode electrode;
a second side surface in contact with the second cathode electrode; and
a first surface which is in contact with the second encapsulation layer and connects the first side surface to the second side surface.

4. The display device of claim 3, wherein the first cathode electrode and the second cathode electrode are electrically connected through the bank layer.

5. The display device of claim 4, wherein the first light emitting layer is in contact with the first side surface, and the second light emitting layer is in contact with the second side surface.

6. The display device of claim 2, wherein the first encapsulation layer comprises a first inorganic layer in contact with the first light emitting element and a second inorganic layer in contact with the second light emitting element, and the first inorganic layer and the second inorganic layer are spaced apart from each other in a portion overlapping the non-emission area.

7. The display device of claim 6, wherein a cavity formed between the bank layer and the first inorganic layer in the direction perpendicular to the substrate has a first height, and a cavity formed between the bank layer and the second inorganic layer has a second height.

8. The display device of claim 7, wherein the first height and the second height are different from each other.

9. The display device of claim 7, wherein the second height is greater than the first height.

10. The display device of claim 3, wherein the first surface is not in contact with the first encapsulation layer, and the first surface is in contact with the second encapsulation layer.

11. The display device of claim 10, wherein the first surface is spaced apart from the first encapsulation layer with the cavity interposed therebetween.

12. The display device of claim 2, further comprising a residual pattern between the first anode electrode and the pixel defining layer in the direction perpendicular to the substrate,
wherein the residual pattern is in contact with the first light emitting layer.

13. The display device of claim 1, wherein in a plan view, the first opening is completely surrounded by the second opening.

14. The display device of claim 4, further comprising an auxiliary encapsulation layer between the first encapsulation layer and the second encapsulation layer,
wherein the auxiliary encapsulation layer completely covers the first encapsulation layer in a portion overlapping the emission area and the non-emission area, and
the auxiliary encapsulation layer is in contact with the first surface, and the auxiliary encapsulation layer completely covers the first surface.

15. A display device comprising:
a substrate comprising a first emission area, a second emission area, and a non-emission area between the first emission area and the second emission area;
a first light emitting element on the first emission area of the substrate;
a second light emitting element on the second emission area of the substrate;
a pixel defining layer on the non-emission area of the substrate and defining a first opening;
a bank layer defining a second opening on the pixel defining layer;
a first inorganic layer on the first light emitting element;
a second inorganic layer on the second light emitting element and spaced apart from the first inorganic layer; and
an organic encapsulation layer on the first inorganic layer and the second inorganic layer,
wherein the first light emitting element and the first inorganic layer are in contact with one side surface of the bank layer facing the first emission area,
the second light emitting element and the second inorganic layer are in contact with the other side surface of the bank layer facing the second emission area, and
the first inorganic layer and the second inorganic layer are spaced apart from each other without overlapping the non-emission area.

16. The display device of claim 15, wherein the first opening is inside the second opening.

17. The display device of claim 16, wherein the bank layer comprises a first surface facing the organic encapsulation layer, and
the first inorganic layer and the second inorganic layer comprise a protrusion which protrudes more toward the organic encapsulation layer than the first surface.

18. The display device of claim 17, further comprising a residual pattern between the substrate and the pixel defining layer in a direction perpendicular to the substrate,
wherein the residual pattern and the protrusion do not overlap each other.

19. A method of fabricating a display device, comprising:
forming a substrate comprising an emission area and a non-emission area, an anode electrode on the emission area of the substrate and a sacrificial layer on the anode electrode, and forming a pixel defining layer completely covering the sacrificial layer and the substrate, and a bank material layer completely covering the pixel defining layer;
forming a photoresist on the bank material layer, etching the bank material layer and the pixel defining layer overlapping the anode electrode to expose the sacrificial layer, and then etching a sidewall of the bank material layer and the sacrificial layer to expose the anode electrode and form a bank layer;
forming a light emitting layer and a cathode electrode on the anode electrode and the photoresist, and forming a first encapsulation layer on the cathode electrode; and
removing the light emitting layer, the cathode electrode, and the first encapsulation layer located in other areas excluding the light emitting layer, the cathode electrode, and the first encapsulation layer located in the emission area and around the emission area,
wherein in the removing of the light emitting layer and the cathode electrode, a cavity is formed between the first encapsulation layer and the bank layer in a direction perpendicular to the substrate.

20. The method of claim 19, wherein in the etching of the sidewall of the bank material layer to form the bank layer, the photoresist forms a tip which protrudes more toward the emission area than a sidewall of the bank layer.
